(19) United States
(12) Patent Application Publication
(10) Pub. No.: US 2026/0162690 A1
(43) Pub. Date: Jun. 11, 2026

(54) MEMORY DEVICES HAVING STRAP REGIONS WITH FEEDTHROUGH VIAS

(71) Applicant: Taiwan Semiconductor Manufacturing Company, Ltd., Hsinchu (TW)

(72) Inventors: Yung-Ting Chang, New Taipei City (TW); Yi-Feng Ting, Taipei City (TW)

(21) Appl. No.: 19/178,178

(22) Filed: Apr. 14, 2025

Related U.S. Application Data
(60) Provisional application No. 63/728,929, filed on Dec. 6, 2024.

(51) Int. Cl. G11C 5/06; H10B 10/00

(52) U.S. Cl. CPC G11C 5/06; H10B 10/12

(57) ABSTRACT

A semiconductor device includes a first memory cell area, a second memory cell area adjacent to the first memory cell area, and a middle strap area interposing the first memory cell area and the second memory cell area. In some embodiments, the middle strap area includes a feedthrough circuit that electrically couples a first metal layer on a frontside of the semiconductor device to a second metal layer on a backside of the semiconductor device. In some embodiments, the feedthrough circuit includes a plurality of contact metal layers disposed over and electrically coupled to a feedthrough via (FTV).

### PRIORITY DATA

This application claims the benefit of U.S. Provisional Application No. 63/728,929 filed Dec. 6, 2024, the entirety of which is herein incorporated.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

As technology nodes become smaller, power signals may be routed to a backside of a semiconductor device for power and chip space optimization. For example, feedthrough vias (FTVs) may be used to connect signals from a frontside of a wafer to a backside of the wafer. This allows for flexibility in forming semiconductor features on both front and backsides of the wafer. However, in some memory devices (e.g., such as static random-access memory (SRAM) devices), formation of FTVs in middle strap or edge strap regions of an SRAM macro may be constrained by layout design placement, making it difficult to maintain process performance. Moreover, in some cases, layout designs for SRAM macros are not efficiently using available chip area, thereby increasing cost and reducing device performance. Thus, existing techniques have not proved entirely satisfactory in all respects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a device including a memory macro with a middle strap area between edge strap areas, in accordance with some embodiments.

FIG. 2 illustrates a circuit diagram of a static random-access memory (SRAM) cell that may be implemented as part of the memory macro in FIG. 1, in accordance with some embodiments.

FIG. 3 illustrates a top view device layout of a portion of the device of FIG. 1 including the middle strap area, in accordance with some embodiments.

FIG. 4 illustrates a cross-sectional view of a semiconductor device along line A-A of FIG. 3 and including a view of a feedthrough circuit, in accordance with some embodiments.

FIG. 5 illustrates an alternative top view device layout of a portion of the device of FIG. 1 including the middle strap area, in accordance with some embodiments.

FIG. 6 illustrates a cross-sectional view of a semiconductor device along line B-B of FIG. 5 and including a view of a feedthrough circuit, in accordance with some embodiments.

FIG. 7 and FIG. 8 illustrate respective top view device layouts of a feedthrough circuit region corresponding to the examples of FIGS. 3 and 5, in accordance with some embodiments.

FIG. 9 illustrates a top view device layout of a portion of the device of FIG. 1 including the edge strap area, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, may be understood to be within +/−10% between the compared features. Further, disclosed dimensions of the different features can implicitly disclose dimension ratios between the different features.

The present disclosure relates to semiconductor devices, and particularly to memory devices such as static random access memory (SRAM) devices having a middle strap area between edge strap areas. The edge strap areas define the edge boundaries of a memory macro. The memory macro includes a plurality of memory cells such as an array of SRAM cells interposing the middle strap area and respective ones of the edge strap areas, each SRAM cell having a plurality of metal routing lines including power line connections that connect to power source or to ground. These power line connections are electrically connected to source/drain (S/D) features in the SRAM cells and provide routing to power pull-up and pull-down transistors of the memory macro. For backside power routing, feedthrough vias (FTVs) may be used to route power from a back side of the memory macro through the edge strap areas and/or from the middle strap area embedded in the memory macro. While edge strap and middle strap areas may not contain any SRAM cells, they may include vertical metal routings to route power signals from a front side of the memory device to a back side of the memory device. In some existing implementations, formation of FTVs in middle strap or edge strap regions of a memory macro (e.g., such as an SRAM macro) may be constrained by layout design placement (e.g., due to use of a single contact feature to contact an FTV), making it difficult to maintain process performance. Moreover, in some cases, layout designs for edge strap and middle strap areas of SRAM macros are not efficiently using available chip area, thereby increasing cost and reducing device performance. Thus, existing techniques have not proved entirely satisfactory in all respects.

Embodiments of the present disclosure offer advantages over the existing art, though it is understood that other embodiments may offer different advantages, not all advantages are necessarily discussed herein, and no particular advantage is required for all embodiments. For example, rather than using a single metal contact feature (e.g., such as a single S/D contact or merge MD layer) to contact an FTV, embodiments discussed herein may provide a plurality of metal contact features (e.g., such as a plurality of S/D contacts or a plurality of slot MD features) to contact the FTV. By employing a plurality of metal contact features (a plurality of slot MD structures), instead of a single metal contact feature (a merge MD structure), layout design is simplified and it is easier to maintain process performance. In addition, embodiments of the present disclosure provide for tuning of an FTV cell size for layout design optimization, including SRAM macro size reduction and device performance improvement. Other embodiments and advantages will be evident to those skilled in the art upon reading the present disclosure.

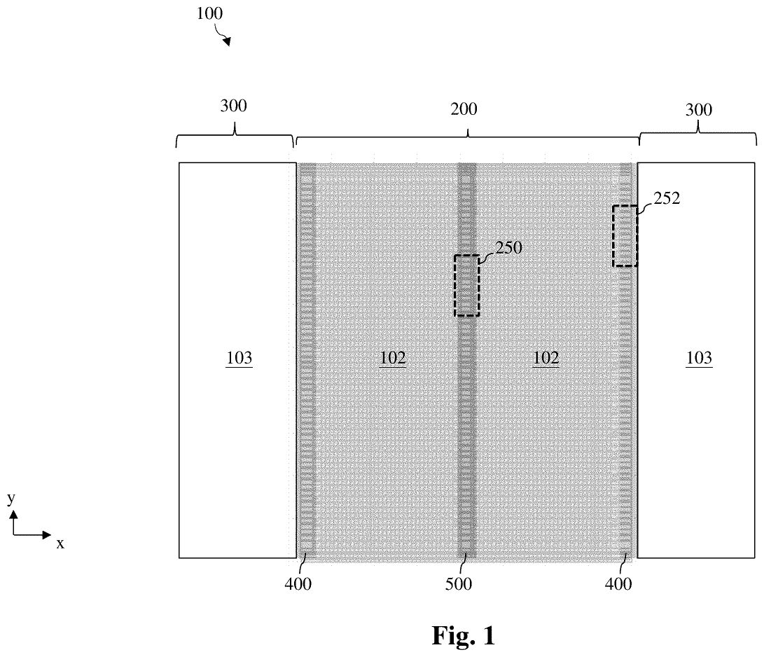

FIG. 1 illustrates a semiconductor device 100 including a memory macro 200, in accordance with some embodiments. In various examples, the memory macro 200 may include an SRAM macro. The semiconductor device 100 may include a substrate, a device layer (e.g., transistors, etc.) over the substrate, a frontside interconnect structure over the device layer, and a backside interconnect structure below the device layer and/or the substrate. The device 100 may be a memory device integrated with logic components. Alternatively, the device 100 may be part of a microprocessor, an application specific integrated circuit (ASIC), a field programmable gate array (FPGA), or a digital signal processor (DSP). The exact functionality of the device 100 is not a limitation to the provided subject matter. The memory macro 200 may be a single-port SRAM macro, a dual-port SRAM macro, or other types of memory macro. The memory macro 200 includes memory cell areas 102 (or SRAM cell areas 102) having a plurality of memory cells for storing a plurality of bits. The semiconductor device 100 may also include peripheral logic circuits 300 adjacent to the memory macro 200 (along the X direction) for implementing various functions such as write and/or read address decoder, word/bit selector, data drivers, memory self-testing, etc. The peripheral logic circuits 300 include logic cell areas 103, which may contain arrays of standard logic cells for implementing input/output (I/O) blocks. Each of the memory cell areas 102 and the logic cell areas 103 may be implemented with various PMOS and NMOS transistors such as planar transistors, FinFET, gate-all-around (GAA) nanosheet transistors, GAA nanowire transistors, or other types of transistors. Further, the memory macro 200 and the logic circuits 300 may include various contact features (or contacts), vias, and metal lines for connecting the source, drain, and gate electrodes (or terminals) of the transistors to form an integrated circuit.

Still referring to FIG. 1, the memory macro 200 includes two edge strap areas 400. The edge strap areas 400 are located at the edges of the memory macro 200 in the X direction and extend lengthwise along the Y direction. The memory macro 200 further includes one or more middle strap areas 500 disposed laterally between the edge strap areas 400 along the X direction. For purposes of simplicity, only one middle strap area 500 is shown. As shown, the memory cell areas 102 interpose the middle strap area 500 and respective ones of the edge strap areas 400 at opposite ends of the memory macro 200. In various embodiments, the edge strap areas 400 and the middle strap area 500 do not store memory bits as they do not contain memory cells and may instead be used for routing power signal lines from a frontside to a backside of the semiconductor device 100. As such, edge strap areas 400 and the middle strap area 500 do not contain any transistors associated with implementing any memory cells.

Still referring to FIG. 1, and in some embodiments, the middle strap area 500 may have larger buffer regions at the edges of the middle strap area 500 along the X direction as compared to the edge strap areas 400. Such buffer regions may provide metal routing and/or isolation from active transistors in the memory cell areas 102 and the logic cell areas 103. The buffer regions disposed adjacent to the memory cell areas 102 may require a greater spacing than the buffer regions disposed adjacent to the logic cell areas 103, for instance, because memory cell routing and isolation may be more sensitive than logic cell routing and isolation. In some embodiments, for the edge strap areas 400, there may be no buffer regions adjacent to the logic cell areas 103. As such, since one side of the edge strap areas 400 is adjacent to a logic cell area 103, and both sides of the middle strap area 500 are adjacent to memory cell areas 102, the middle strap area 500 may in some cases span a wider distance in the X direction than the edge strap areas 400. In various embodiments, the memory cell areas 102 and the logic cell areas 103 may provide metal routing lines including power line connections that connect to power source or to ground. Further, the semiconductor device 100 includes backside interconnect features to provide backside power routing. As described in more detail herein, the middle strap area 500 and/or the edge strap areas 400 may include feedthrough vias (FTVs) for electrically connecting front and back sides of the semiconductor device 100.

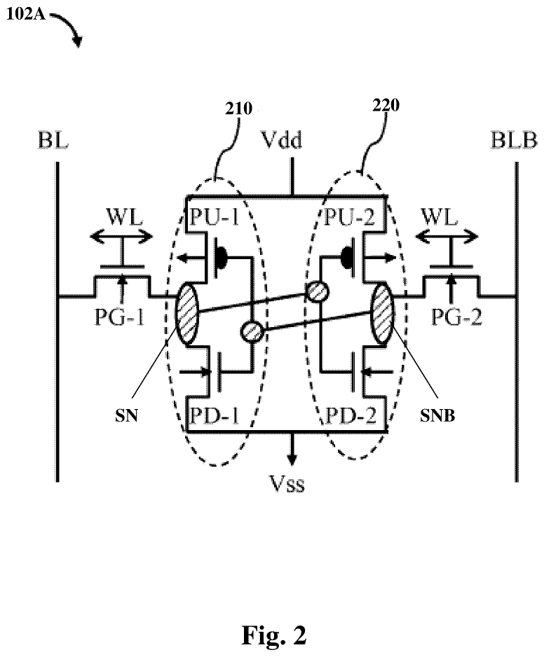

FIG. 2 illustrates an exemplary circuit diagram of an SRAM cell 102A, which may be implemented as part of the memory cell areas 102 of the memory macro 200 in FIG. 1. For instance, in various embodiments, a plurality of SRAM cells 102A defines an array of SRAM cells 102A that may be implemented as part of the memory cell areas 102 of the memory macro 200. While FIG. 2 illustrates a single-port SRAM cell, it will be understood that the various disclosed embodiments may be equally implemented in a multi-port SRAM cell (e.g., such as a dual-port SRAM cell), without departing from the scope of the present disclosure. FIG. 2 has been simplified for the sake of clarity to better understand the inventive concepts of the present disclosure. Additional features can be added in the SRAM cell 200, and some of the features described below can be replaced, modified, or eliminated in other embodiments of SRAM cell 200.

The SRAM cell 102A includes six transistors: a pass-gate transistor PG-1, a pass-gate transistor PG-2, a pull-up transistor PU-1, a pull-up transistor PU-2, a pull-down transistor PD-1, and a pull-down transistor PD-2. Thus, in some examples, the SRAM cell 102A may be referred to as a 6T SRAM cell. In operation, pass-gate transistor PG-1 and pass-gate transistor PG-2 provide access to a storage portion of the SRAM cell 102A, which includes a cross-coupled pair of inverters, an inverter 210 and an inverter 220. Inverter 210 includes the pull-up transistor PU-1 and the pull-down transistor PD-1, and inverter 220 includes the pull-up transistor PU-2 and the pull-down transistor PD-2. In some implementations, pull-up transistors PU-1, PU-2 are configured as P-type transistors, the pull-down transistors PD-1, PD-2 are configured as N-type transistors, and the pass-gate transistors PG-1, PG-2 are also configured as N-type transistors. The P-type and N-type transistors used to form respective transistors of the SRAM cell 102A may include planar transistors, FinFETs, GAA transistors, or other types of transistors.

A gate of pull-up transistor PU-1 interposes a source (electrically coupled with a power supply voltage (V_{DD})) and a first common drain (CD1), and a gate of pull-down transistor PD-1 interposes a source (electrically coupled with a power supply voltage (V_{SS})) and the first common drain. A gate of pull-up transistor PU-2 interposes a source (electrically coupled with power supply voltage (V_{DD})) and a second common drain (CD2), and a gate of pull-down transistor PD-2 interposes a source (electrically coupled with power supply voltage (V_{SS})) and the second common drain. In some implementations, the first common drain (CD1) is a storage node (SN) that stores data in true form, and the second common drain (CD2) is a storage node (SNB) that stores data in complementary form. The gate of pull-up transistor PU-1 and the gate of pull-down transistor PD-1 are coupled with the second common drain, and the gate of pull-up transistor PU-2 and the gate of pull-down transistor PD-2 are coupled with the first common drain. A gate of pass-gate transistor PG-1 interposes a source (electrically coupled with a bit line BL) and a drain, which is electrically coupled with the first common drain. A gate of pass-gate transistor PG-2 interposes a source (electrically coupled with a complementary bit line BLB) and a drain, which is electrically coupled with the second common drain. The gates of pass-gate transistors PG-1, PG-2 are electrically coupled with a word line WL. In some implementations, pass-gate transistors PG-1, PG-2 provide access to storage nodes SN, SNB during read operations and/or write operations. For example, pass-gate transistors PG-1, PG-2 couple storage nodes SN, SN-B respectively to bit lines BL, BLB in response to voltage applied to the gates of pass-gate transistors PG-1, PG-2 by WLs.

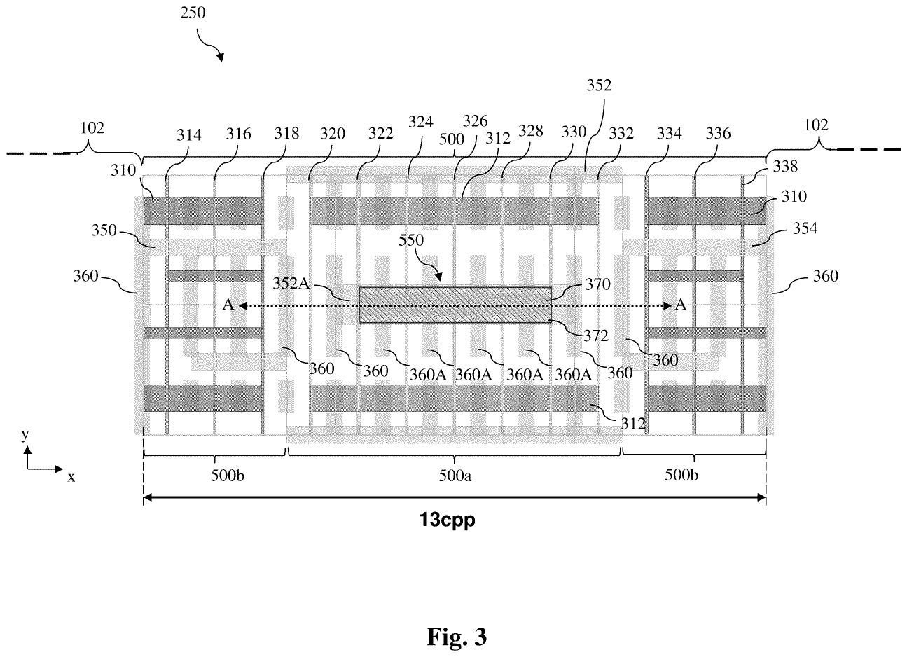

Referring to FIG. 3, shown therein is a top view (or a layout) of an area 250 of FIG. 1, according to some aspects of the present disclosure. As shown, the area 250 includes a portion of the middle strap area 500 and very small portions of the memory cell areas 102 disposed on either side of the middle strap area 500 in the X direction. The middle strap area 500 and the memory cell areas 102 each include a plurality of active regions, such as active regions 310 and 312. Source/drain features and/or a channel region of a transistor may be formed in or on the active regions, such as the active regions 310 and 312. The active regions 310 and 312 each extend in the X-direction. The active region 310 may be located the middle strap area 500, or in some cases may extend from the memory cell area 102 into the middle strap area 500. In other words, in some cases, a portion of the active region 310 may be in the memory cell area 102, and another portion of the active region 310 may be in the middle strap area 500. Alternatively, in some cases, the active region 310 may be entirely in the middle strap area 500. In some examples, the active region 312 is located in the middle strap area 500, but not in the memory cell area 102.

The area 250 illustrated in FIG. 3 also includes a plurality of gate structures, such as gate structures 314, 316, 318, 320, 322, 324, 326, 328, 330, 332, 334, 336, and 338. The gate structures 314-338 each extend in the Y-direction that is perpendicular to the X-direction. In some embodiments, the gate structures 314-338 may include dummy polysilicon gates. In some embodiments, the gate structures 314-338 may include high-K/metal gate structures that are formed by a gate replacement process. In a gate replacement process, dummy gate structures (e.g., dummy polysilicon gate structures) may be initially formed, and following the formation of source/drain features, the dummy gate structures are removed and replaced by the high-K/metal gate structures. The high-K/metal gate structures may each include a high-K gate dielectric and a metal gate electrode. For purposes of this discussion, a high-K gate dielectric is a dielectric having a dielectric constant greater than about 3.9.

The middle strap area 500 and the memory cell areas 102 may further include a plurality of electrical isolation structures that intersect with the gate structures in the top view. For example, an electrical isolation structure 350 intersects with the gate structures 314, 316, and 318. In some embodiments, the electrical isolation structure 350 may be located the middle strap area 500, or in some cases may extend from a memory cell area 102 (on a first side of the middle strap area 500) into the middle strap area 500. Meanwhile, an electrical isolation structure 352 is located in the middle strap area 350, where the electrical isolation structure 352 intersects with the gate structures 320, 322, 324, 326, 328, 330, and 332. Further, an electrical isolation structure 354 intersects with the gate structures 334, 336, and 338. In some embodiments, the electrical isolation structure 354 may be located the middle strap area 500, or in some cases may extend from a memory cell area 102 (on a second side of the middle strap area 500 opposite the first side) into the middle strap area 500. The electrical isolation structures 350, 352, and 354 each extend in the X-direction. In some embodiments, the electrical isolation structures 350, 352, and 354 may be formed by etching openings that extend vertically through at least some of the gate structures, and subsequently filling the etched openings with one or more dielectric materials (e.g., such as silicon oxide, silicon nitride, silicon carbide, silicon oxynitride, etc.). The dielectric materials filling the openings provide electrical isolation, which allows the electrical isolation structures 350, 352, and 354 to cut each of the gate structures into multiple segments that are electrically isolated from each other. Thus, in some cases, the electrical isolation structures may be equivalently referred to as gate cut features.

The area 250 shown in FIG. 3 also includes a plurality of contact metal layers, such as contact metal layers 360. The contact metal layers 360 each extend in the Y-direction that is perpendicular to the X-direction. In some examples, the contact metal layers 360 may be used to provide a connection to a source/drain feature in a source/drain region. As described in more detail below, a set of contact metal layers 360A in the middle strap area 500 may provide a plurality of metal contact features (a plurality of slot MD features) used to contact a feedthrough via (FTV) in the middle strap area 500.

As shown in FIG. 3, the middle strap area 500 also includes a feedthrough circuit region 500a sandwiched between buffer regions 500b along the X direction. The feedthrough circuit region 500a includes a feedthrough circuit 550 disposed between active regions 312 along the Y direction. As described in more detail below, the feedthrough circuit 550 includes the FTV used for backside power routing. The buffer regions 500b include the active regions 310, which is some cases may extend from the memory cell areas 102 into the middle strap area 500 on either side of the middle strap area 500. In some embodiments, frontside vias (not shown) may be formed over one or more of the contact metal layers 360 disposed along a boundary between the middle strap area 500 and the memory cell areas 102. Such frontside vias, by way of example, may define the edge boundaries of the middle strap area 500, and may further define where the memory cell areas 102 begin.

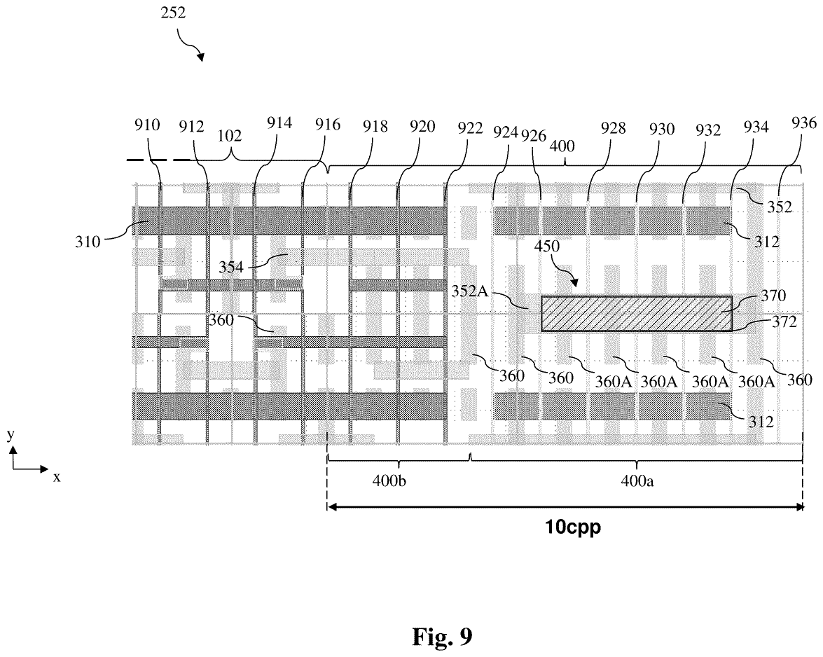

In the example shown, the middle strap area 500 may span a width of 13 gate pitches (also referred to as contacted poly pitch or CPP), where each gate pitch or each CPP is defined as a distance between an adjacent pair of gate structures along the X direction (e.g., such as adjacent gate structures 320 and 322). In some embodiments, the feedthrough circuit region 500a may span 7 gate pitches while each of the buffer regions 500b may span 3 gate pitches, adding up to a total of 13 gate pitches. In some cases, an edge strap area 400 (see FIG. 9) may only span a width of 10 gate pitches. Also, in some embodiments, the edge strap area 400 may be configured similarly to the middle strap area 500, but instead of having two buffer regions, the edge strap area 400 may only have one buffer region located an interface between the edge strap area and the memory cell area 102. For example, in some cases, the edge strap area 400 may have a feedthrough circuit region that spans 7 gate pitches and a single buffer region that spans 3 gate pitches, adding up to a total of 10 gate pitches.

Referring again to the feedthrough circuit 550 as shown in FIG. 3, the feedthrough circuit 550 includes a source/drain contact via rail (VDR) 370 that is disposed over and connected to the set of contact metal layers 360A (slot MD features), and the set of contact metal layers 360A that is disposed over and connected to a feedthrough via (FTV) 372. In various embodiments, the VDR 370, the set of contact metal layers 360A, and the FTV 372 are used to electrically connect front and back sides of a semiconductor device. Specifically, by way of example, the feedthrough circuit 550 is used to electrically connect a frontside interconnect structure (e.g., such as a metal line in a frontside metal layer, M0) to a backside interconnect structure (e.g., such as a metal line in a backside metal layer, BM0). In addition, the feedthrough circuit 550 includes an electrical isolation structure 352A that surrounds the FTV 372, in a top view.

In some embodiments, the electrical isolation structure 352A may be similar to the electrical isolation structure 352, discussed above. The electrical isolation structure 352A intersects with the gate structures 322, 324, 326, 328, and 330, and may be formed in a similar manner as described above with reference to the isolation structure 352. In contrast to the electrical isolation structure 352, the electrical isolation structure 352A has different dimensions than the electrical isolation structure 352. In particular, the electrical isolation structure 352A is sized to fully surround the FTV 372, in a top view, thereby providing effective FTV-FTV isolation. Also, in some embodiments, the FTV 372 may be center-aligned to the gate structures of the middle strap area 500. In the example shown, the FTV 372 has a width of 4 gate pitches, which is longer than some existing implementations and thus provides for reduced resistance. It is also noted that other FTV widths are possible, and within the scope of the present disclosure, as discussed in more detail below. As further shown, the FTV 372 may extend beyond the upper and lower edges of the VDR 370 in the Y-direction, while having substantially overlapping lateral edges in the X-direction, in the top view. Additionally, as shown in the top view of FIG. 3, the upper and lower edges of the set of contact metal layers 360A extend beyond the upper and lower edges of the VDR 370, the FTV 372, and the electrical isolation structure 352A in the Y-direction. By employing the set of contact metal layers 360A (the set of slot MD structures), instead of a single metal contact feature (a merge MD structure) as used in some existing implementations, layout design is simplified and process window is increased, thereby making it easier to maintain process performance.

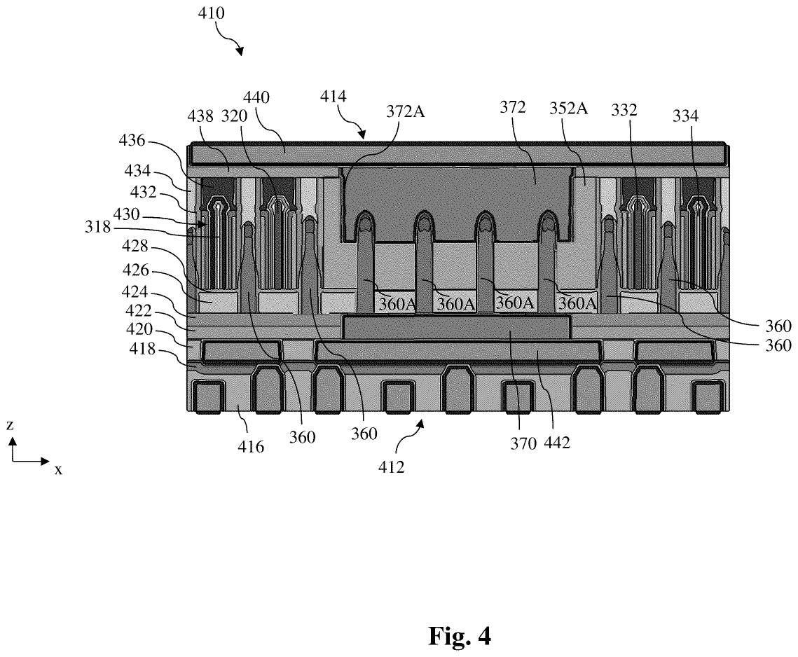

Referring to FIG. 4, illustrated therein is a cross-sectional view of a semiconductor device 410 along line A-A of FIG. 3 and including a view of the feedthrough circuit 550, in accordance with some embodiments. The semiconductor device 410 has a front side 412 and a back side 414. As shown in FIG. 4, the device 410 may include various interlayer dielectric (ILD) layers 416, 420, 422, 426, and 434, etch stop layers 418, 424, 428, and 432, sidewall spacer layers 430, shallow trench isolation (STI) features 436, and backside hard mask layers 438 that embed metal features.

The metal features make up the feedthrough circuit 550, discussed above, and the metal features may include the feedthrough via (FTV) 372 penetrating from the back side 414 through a first portion of the semiconductor device 410, the set of contact metal layers 360A (slot MD features) penetrating from the front side 412 through a second portion of the semiconductor device 410, and the source/drain contact via rail (VDR) 370 penetrating from the front side 412 through a third portion of the semiconductor device 410. As shown, the FTV 372 is electrically coupled to a first end of each contact metal layer 360A of the set of contact metal layers 360A (slot MD features), and the source/drain contact via rail (VDR) 370 is electrically coupled to a second end of each contact metal layer 360A of the set of contact metal layers 360A (slot MD features). In the embodiment shown, the FTV 372 may penetrate through one or more backside hard mask layers 438 and a portion of the electrical isolation structure 352A. In particular, as discussed above, the electrical isolation structure 352A fully surrounds the FTV 372, in a top view, thereby providing effective FTV-FTV isolation.

As also shown in FIG. 4, the FTV 372 lands on a backside metal line 440 (BM0) disposed on the back side 414 of the semiconductor device 410. The backside metal line 440 (BM0) may be part of a backside metal interconnect structure (not shown), which includes additional stacked backside metals vertically connected by additional backside interconnect vias for backside power signal routing (e.g., Vss or Vdd). The set of contact metal layers 360A (slot MD features) may penetrate through a portion of the electrical isolation structure 352A and portions of the ILD layer 426 to land on a top surface of the FTV 372. The source/drain contact via rail (VDR) 370 may penetrate through the ILD layer 422 and the etch stop layer 424 to land on a top surface of the set of contact metal layers 360A (slot MD features). Further, a frontside metal line 442 (M0) is disposed on the front side 412 of the semiconductor device 410 and lands on a top surface of the source/drain contact via rail (VDR) 370. The frontside metal line 442 (M0) may be part of a frontside metal interconnect structure, which includes additional stacked frontside metals vertically connected by additional frontside interconnect vias.

In some embodiments, etch stop layers 418, 424, 428, and 432 and hard mask layer(s) 438 may include different dielectric materials from the ILD layers 416, 420, 422, 426, and 434 to provide appropriate etchant selectivity. For example, the etch stop layers 418, 424, 428, and 432 and hard mask layer(s) 438 may include a nitride-based dielectric such as silicon nitride, silicon oxynitride, silicon carbonitride, silicon carbon oxynitride, or combinations thereof. Further, the ILD layers 416, 420, 422, 426, and 434 may include silicon oxide or an oxide-based dielectric formed with tetraethylorthosilicate, un-doped silicate glass, or doped silicon oxide such as borophosphosilicate glass (BPSG), fluoride-doped silica glass (FSG), phosphosilicate glass (PSG), boron doped silicon glass (BSG), a low-K dielectric material, other suitable dielectric material, or combinations thereof. Additionally, in some embodiments, the metal features that make up the feedthrough circuit 550 (e.g., the FTV 372, the set of contact metal layers 360A, and the VDR 370) may include Cu, Al, an AlCu alloy, Ru, Co, W, or other appropriate metal layer. In some cases, a barrier or liner layer may be deposited prior to depositing a bulk metal layer to form each of the metal features that make up the feedthrough circuit 550. As one example, the FTV 372 may include a liner layer 372A (e.g., such as Ti or TiN) that is formed prior to deposition of the bulk metal layer used to provide the FTV 372.

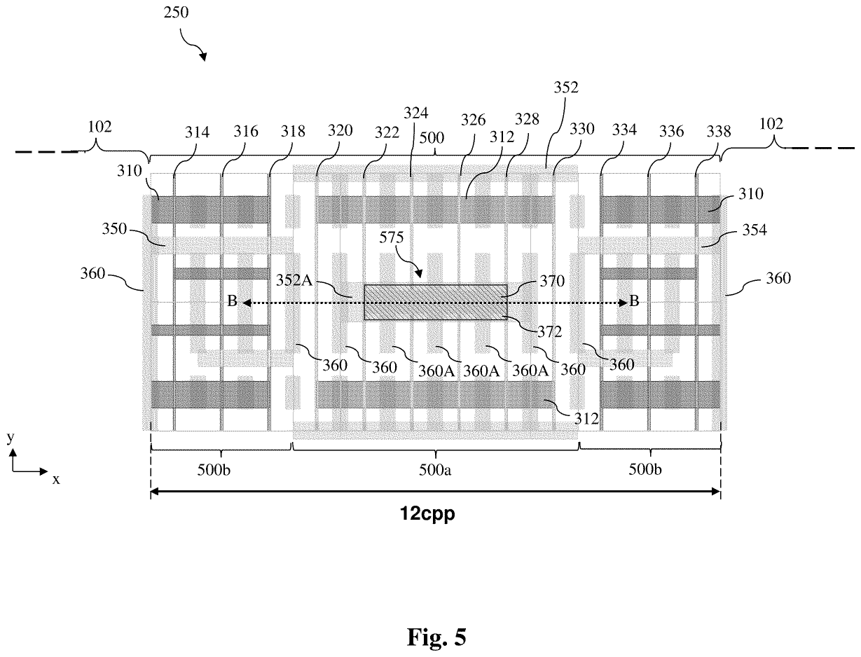

Referring to FIG. 5, shown therein is a top view (or a layout) of the area 250 of FIG. 1, according to other aspects of the present disclosure. The example illustrated in FIG. 5 is similar to the example described above with reference to FIG. 3, and like features are shown and described using like reference numbers. In the discussion that follows, and for the sake of clarity, the discussion of the embodiment of FIG. 5 will focus primarily on the differences as compared to the embodiment of FIG. 3. Like the example shown in FIG. 3, the example layout shown in FIG. 5 includes a portion of the middle strap area 500 and very small portions of the memory cell areas 102 disposed on either side of the middle strap area 500 in the X direction. The middle strap area 500 and the memory cell areas 102 each include a plurality of active regions, such as active regions 310 and 312, as previously discussed.

The area 250 illustrated in FIG. 5 also includes a plurality of gate structures, such as gate structures 314, 316, 318, 320, 322, 324, 326, 328, 330, 334, 336, and 338. The gate structures 314-330 and 334-338 each extend in the Y-direction that is perpendicular to the X-direction. The gate structures 314-330 and 334-338 may be substantially the same as the gate structures 314-338, discussed above. However, in the example of FIG. 5, one gate structure (the gate structure 332, in this example) has been removed, thereby reducing a width of the middle strap area 500 to 12 gate pitches, as compared to the width of the middle strap area 500 in the example of FIG. 3 (13 gate pitches), as discussed in more detail below. Thus, considering the embodiments of FIGS. 3 and 5, aspects of the present disclosure provide for a tunable size of the middle strap area 500 and for an area reduction of the memory macro 200.

The example of FIG. 5 also includes a plurality of electrical isolation structures that intersect with the gate structures in the top view, such as the electrical isolation structure 350, the electrical isolation structure 352, and the electrical isolation structure 354, discussed above and which extend in the X-direction. The area 250 shown in FIG. 5 also includes a plurality of contact metal layers, such as contact metal layers 360, discussed above. Further, the embodiment of FIG. 5 also includes a set of contact metal layers 360A in the middle strap area 500 that may provide a plurality of metal contact features (a plurality of slot MD features) used to contact a feedthrough via (FTV) in the middle strap area 500. However, due to the reduced width of the middle strap area 500 in the example of FIG. 5, the set of contact metal layers 360A includes three contact metal layers 360A, as compared to four contact metal layers 360 shown in the example of FIG. 3. It will be understood that in other embodiments and depending on the width of the middle strap area 500, the set of contact metal layers 360A may include five, six, or another number of contact metal layers 360A (slot MD features).

Like the example of FIG. 3, the example of FIG. 5 shows the middle strap area 500 including the feedthrough circuit region 500a sandwiched between buffer regions 500b along the X direction. The feedthrough circuit region 500a includes a feedthrough circuit 575 disposed between active regions 312 along the Y direction. The feedthrough circuit 575 is substantially similar to the feedthrough circuit 550, described above, and thus may also include an FTV used for backside power routing. However, the feedthrough circuit 575 has a reduced width and utilizes a smaller number of contact metal layers 360A (slot MD features) as compared to the feedthrough circuit 550. The buffer regions 500b may be substantially the same as described above. In the example of FIG. 5, the middle strap area 500 may span a width of 12 gate pitches, which is smaller than the width of the example of FIG. 3 (13 gate pitches). In particular, and in the embodiment of FIG. 5, the feedthrough circuit region 500a may span 6 gate pitches (in contrast to the 7 gate pitch width of the feedthrough circuit region 500a of FIG. 3) while each of the buffer regions 500b may span 3 gate pitches, adding up to a total of 12 gate pitches.

Like the feedthrough circuit 550, the feedthrough circuit 575 of FIG. 5 includes the source/drain contact via rail (VDR) 370 that is disposed over and connected to the set of contact metal layers 360A (slot MD features), and the set of contact metal layers 360A that is disposed over and connected to the feedthrough via (FTV) 372. As discussed above, the VDR 370, the set of contact metal layers 360A, and the FTV 372 are used to electrically connect front and back sides of a semiconductor device. Specifically, by way of example, the feedthrough circuit 575 is used to electrically connect a frontside interconnect structure (e.g., such as a metal line in a frontside metal layer, M0) to a backside interconnect structure (e.g., such as a metal line in a backside metal layer, BM0). In addition, the feedthrough circuit 575 includes the electrical isolation structure 352A that surrounds the FTV 372, in a top view.

The electrical isolation structure 352A may be similar to (and may be formed in a similar manner as) the electrical isolation structure 352, as previously noted. However, in the example of FIG. 5 and due to the reduced widths of the middle strap area 500 and the feedthrough circuit 575, the electrical isolation structure 352A intersects with a smaller number of gate structures (gate structures 322, 324, 326, and 328), as compared to the example of FIG. 3. As shown, the electrical isolation structure 352A is sized to fully surround the FTV 372, in a top view, thereby providing effective FTV-FTV isolation. Also, in the example of FIG. 5, the FTV 372 may be center-aligned to the slot MD structures (the contact metal layers 360, 360A) of the middle strap area 500. In the example of FIG. 5, the FTV 372 has a width of 3 gate pitches, which is shorter than the example of FIG. 3 but may still be longer than some existing implementations and thus may still provide for reduced resistance. As further shown in the example of FIG. 5, and like the example of FIG. 3, the FTV 372 may extend beyond the upper and lower edges of the VDR 370 in the Y-direction, while having substantially overlapping lateral edges in the X-direction, in the top view. Additionally, as shown in the top view of FIG. 5 and similar to the example of FIG. 3, the upper and lower edges of the set of contact metal layers 360A extend beyond the upper and lower edges of the VDR 370, the FTV 372, and the electrical isolation structure 352A in the Y-direction. As previously described, by employing the set of contact metal layers 360A (even the reduced set of contact metal layers 360A as in the example of FIG. 5), instead of a single metal contact feature (a merge MD structure) as used in some existing implementations, layout design is simplified and process window is increased, thereby making it easier to maintain process performance.

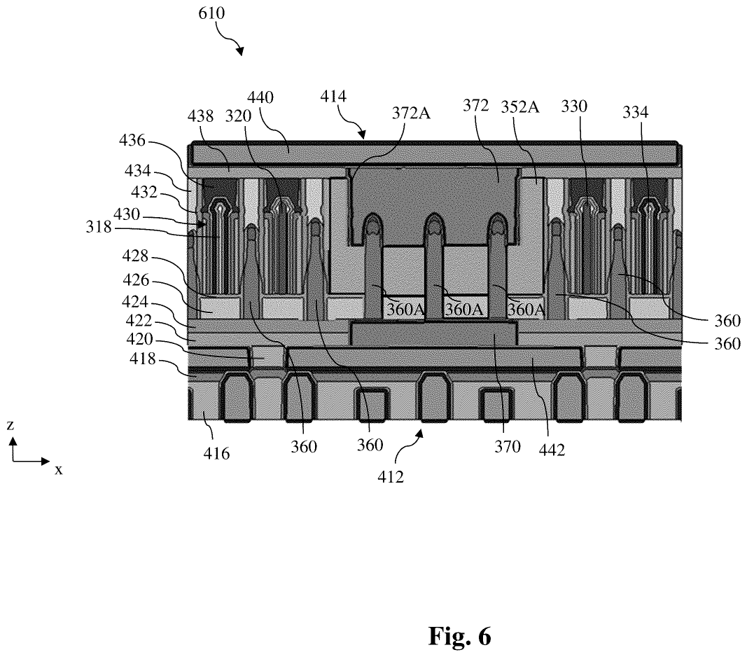

Referring to FIG. 6, illustrated therein is a cross-sectional view of a semiconductor device 610 along line B-B of FIG. 5 and including a view of the feedthrough circuit 575, in accordance with some embodiments. The example illustrated in FIG. 6 is similar to the example described above with reference to FIG. 4, and like features are shown and described using like reference numbers. In the discussion that follows, and for the sake of clarity, the discussion of the embodiment of FIG. 6 will focus primarily on the differences as compared to the embodiment of FIG. 4. Like the example shown in FIG. 4, the embodiment of FIG. 6 includes the front side 412 and the back side 414. Further, the device 610 of FIG. 6 also includes the ILD layers 416, 420, 422, 426, and 434, etch stop layers 418, 424, 428, and 432, sidewall spacer layers 430, STI features 436, and backside hard mask layers 438 that embed metal features.

The metal features make up the feedthrough circuit 575, discussed above, and the metal features may include the FTV 372 penetrating from the back side 414 through a first portion of the semiconductor device 610, the set of contact metal layers 360A (slot MD features) penetrating from the front side 412 through a second portion of the semiconductor device 610, and the VDR 370 penetrating from the front side 412 through a third portion of the semiconductor device 610. As shown, the FTV 372 is electrically coupled to a first end of each contact metal layer 360A of the set of contact metal layers 360A (slot MD features), and the VDR 370 is electrically coupled to a second end of each contact metal layer 360A of the set of contact metal layers 360A (slot MD features). However, due to the smaller number of contact metal layers 360A in the present example (as compared to the feedthrough circuit 550), each of the FTV 372 and the VDR 370 contact a smaller number of contact metal layers 360A. In the embodiment shown, the FTV 372 may also penetrate through one or more backside hard mask layers 438 and a portion of the electrical isolation structure 352A. In particular, as also discussed above, the electrical isolation structure 352A fully surrounds the FTV 372, in a top view, thereby providing effective FTV-FTV isolation.

As also shown in FIG. 6, similar to the example of FIG. 4, the FTV 372 lands on the backside metal line 440 (BM0) disposed on the back side 414 of the semiconductor device 610, as discussed above. Like the example of FIG. 4, the example of FIG. 6 also shows that the set of contact metal layers 360A (slot MD features) may penetrate through a portion of the electrical isolation structure 352A and portions of the ILD layer 426 to land on a top surface of the FTV 372. Due to the smaller number of contact metal layers 360A in the semiconductor device 610 (as compared to the device 410), the width of the FTV 372 may be smaller for the device 610 that the device 410. The VDR 370 may likewise penetrate through the ILD layer 422 and the etch stop layer 424 to land on a top surface of the set of contact metal layers 360A (slot MD features). Once again, due to the smaller number of contact metal layers 360A in the semiconductor device 610 (as compared to the device 410), the width of the VDR 370 may be smaller for the device 610 than the device 410. The example of FIG. 6 also shows that the frontside metal line 442 (M0) is disposed on the front side 412 of the semiconductor device 610 and lands on a top surface of the VDR 370, as discussed above. In some embodiments, the materials used for each of the etch stop layers 418, 424, 428, and 432, the hard mask layer(s) 438, and the ILD layers 416, 420, 422, 426, and 434, may be substantially the same as described above with reference to the example of FIG. 4. In addition, and in various examples, the materials used for each of the metal features that make up the feedthrough circuit 575 (e.g., the FTV 372, the set of contact metal layers 360A, and the VDR 370), as well as materials used for any barrier or liner layers associated with the metal features (e.g., such as barrier or liner layers that may be deposited prior to depositing a bulk metal layer to form each of the metal features that make up the feedthrough circuit 575, such as the liner layer 372A, as one example), may be substantially the same as described above with reference to the example of FIG. 4.

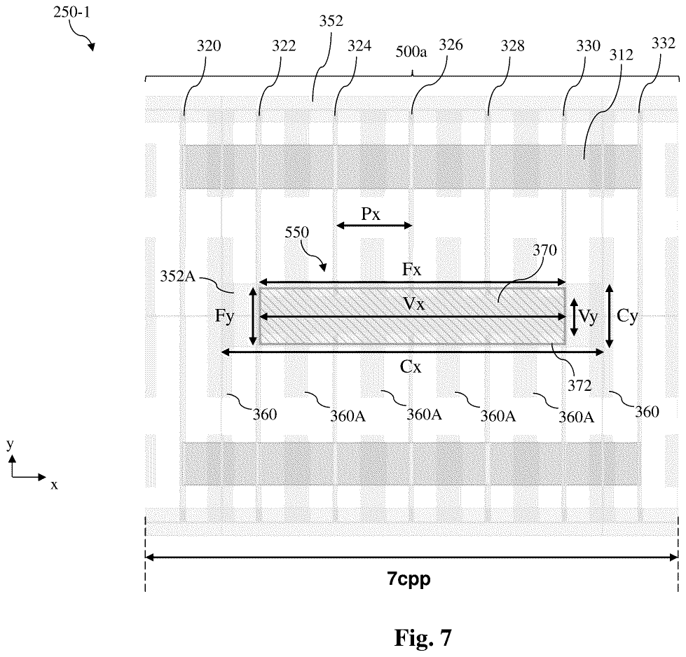

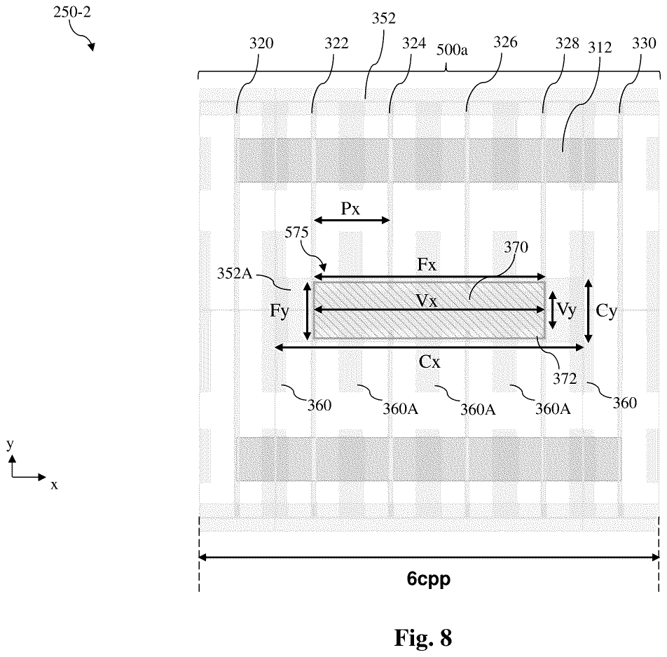

As discussed above with reference to the embodiments of FIGS. 3 and 5, aspects of the present disclosure provide for a tunable size of the middle strap area 500. More particularly, and in various embodiments, the size of the middle strap area 500 may be tuned by modifying the size of the feedthrough circuit region 500a (and the features formed therein). To provide further details regarding the sizing of the middle strap area 500, reference is now made to FIGS. 7 and 8, which show respective top views (or layouts) 250-1 and 250-2 of the feedthrough circuit region 500a corresponding to the embodiments of FIGS. 3 and 5, discussed above. In particular, FIGS. 7 and 8 illustrate dimensions of various features of the layout designs for which corresponding design rules may be applied, in order to provide the disclosed tunable middle strap area 500.

For example, FIGS. 7 and 8 illustrate a dimension Px, which is the gate pitch (or CPP); a dimension Fx, which is the X-direction dimension for the FTV 372; a dimension Fy, which is the Y-direction dimension for the FTV 372; a dimension Cx, which is the X-direction dimension for the electrical isolation structure 352A; and a dimensions Cy, which is the Y-direction dimension for the electrical isolation structure 352A. In some embodiments, relationships between the X-direction dimension (Fx) and the Y-direction dimension (Fy) of the FTV 372 and the gate pitch (Px), respectively, may be defined as 3≤Fx/Px and 0.5<Fy/Px<1.5. In other words, in various embodiments, the X-direction dimension (Fx) of the FTV 372 is at least three times greater than the gate pitch, and the Y-direction dimension (Fy) of the FTV 372 is at least greater than half the size of the gate pitch but less than one-and-a-half the size of the gate pitch. In some embodiments, relationships between the X-direction dimension (Cx) and the Y-direction dimension (Cy) of the electrical isolation structure 352A and the gate pitch (Px), respectively, may be defined as 4≤Cx/Px and 0.5<Cy/Px<1.5. In other words, in various embodiments, the X-direction dimension (Cx) of the electrical isolation structure 352A is at least four times greater than the gate pitch, and the Y-direction dimension (Cy) of the electrical isolation structure 352A is at least greater than half the size of the gate pitch but less than one-and-a-half the size of the gate pitch. Regardless of the specific dimensions chosen, and in accordance with embodiments of the present disclosure, it is noted that Cx and Cy will remain greater than Fx and Fy, respectively, to ensure that the electrical isolation structure 352A fully surrounds the FTV 372, in a top view, to provide complete and effective FTV-FTV isolation. In some embodiments, a dimension Vx, which is the X-direction dimension for the VDR 370, and a dimension Vy, which is the Y-direction dimension for the VDR 370, may also be defined. In some examples, and with reference to the embodiment of FIG. 7, a ratio Cy/Fy is in a range between about 1.1-1.2, a ratio Cy/Vy is in a range between about 1.5-1.9, a ratio Fy/Vy is in a range between about 1.3-1.6, a ratio Cx/Fx is in a range between about 1.2-1.3. In some cases, Fx is equal to Vx, so a ratio Cx/Vx may also be in a range between about 1.2-1.3. In some cases, and with reference to the embodiment of FIG. 8, a ratio Cy/Fy is in a range between about 1.1-1.2, a ratio Cy/Vy is in a range between about 1.5-1.9, a ratio Fy/Vy is in a range between about 1.3-1.6, a ratio Cx/Fx is in a range between about 1.3-1.4. In some cases, Fx is equal to Vx, so a ratio Cx/Vx may also be in a range between about 1.3-1.4.

In addition to forming FTVs in the middle strap areas 500, as described above, FTVs for electrically connecting front and back sides of the semiconductor device 100 may be formed in edge strap areas 400, as shown in FIG. 9. FIG. 9 illustrates a top view (or a layout) of an area 252 of FIG. 1, according to some aspects of the present disclosure. The example layout shown in FIG. 9 includes a portion of the edge strap area 400 and a portion of the memory cell area 102 disposed adjacent to the edge strap area 400 in the X direction. The edge strap area 400 and the memory cell area 102 each include a plurality of active regions, such as active regions 310 and 312, as previously discussed. As shown, the example of FIG. 9 may include similar layers and/or features as previously described with reference to FIGS. 3 and 5. As such, the example of FIG. 9 may show and describe such similar layers and/or features using similar reference numbers as used above.

The area 252 illustrated in FIG. 9 includes a plurality of gate structures, such as gate structures 910, 912, 914, 916, 918, 920, 922, 924, 926, 928, 930, 932, 934, and 936. The gate structures 910-936 each extend in the Y-direction that is perpendicular to the X-direction. The gate structures 910-936 may be substantially the same as the gate structures 314-338, discussed above. The example of FIG. 9 also includes a plurality of electrical isolation structures that intersect with the gate structures in the top view, such as the electrical isolation structure 352 and the electrical isolation structure 354, discussed above and which extend in the X-direction. The area 252 shown in FIG. 9 also includes a plurality of contact metal layers, such as contact metal layers 360, discussed above. Further, the embodiment of FIG. 9 also includes a set of contact metal layers 360A in the edge strap area 400 that may provide a plurality of metal contact features (a plurality of slot MD features) used to contact a feedthrough via (FTV) in the edge strap area 400. In the example of FIG. 9, the set of contact metal layers 360A includes four contact metal layers 360A, similar to the set of contact metal layers 360 used in the middle strap area 500 in the example of FIG. 3. It will be understood that in other embodiments and depending on the width of the edge strap area 400, the set of contact metal layers 360A may include three, five, six, or another number of contact metal layers 360A (slot MD features).

As shown in the example of FIG. 9, the edge strap area 400 includes a feedthrough circuit region 400a and a buffer region 400b, where the buffer region 400b is disposed between the feedthrough circuit region 400a and the memory cell area 102, along the X direction. For the edge strap area 400, there may be no buffer region adjacent to the logic cell area 103. Thus, the edge strap area 400 may only include the single buffer region 400b on one side of the feedthrough circuit region 400a, as shown. It will be understood that in the other edge strap area 400 located at the opposite end of the memory macro (FIG. 1), the buffer region 400b may be disposed on the opposite side of the feedthrough circuit region 400a, in comparison to the example of FIG. 9. The feedthrough circuit region 400a includes a feedthrough circuit 450 disposed between active regions 312 along the Y direction. The feedthrough circuit 450 may be substantially similar to the feedthrough circuit 550, described above, and thus may also include an FTV used for backside power routing. In some embodiments, the buffer region 400b may be similar to the buffer regions 500b, described above. In the example of FIG. 9, the edge strap area 400 may span a width of 10 gate pitches, due to having only a single buffer region 400b. In particular, and in the embodiment of FIG. 9, the feedthrough circuit region 400a may span 7 gate pitches while the buffer region 400b may span 3 gate pitches, adding up to a total of 10 gate pitches.

Like the feedthrough circuit 550, the feedthrough circuit 450 of FIG. 9 includes the source/drain contact via rail (VDR) 370 that is disposed over and connected to the set of contact metal layers 360A (slot MD features), and the set of contact metal layers 360A that is disposed over and connected to the feedthrough via (FTV) 372. As discussed above, the VDR 370, the set of contact metal layers 360A, and the FTV 372 are used to electrically connect front and back sides of a semiconductor device. Specifically, by way of example, the feedthrough circuit 450 is used to electrically connect a frontside interconnect structure (e.g., such as a metal line in a frontside metal layer, M0) to a backside interconnect structure (e.g., such as a metal line in a backside metal layer, BM0). In addition, the feedthrough circuit 450 includes the electrical isolation structure 352A that surrounds the FTV 372, in a top view.

The electrical isolation structure 352A may be similar to (and may be formed in a similar manner as) the electrical isolation structure 352, as previously noted. As shown, the electrical isolation structure 352A is sized to fully surround the FTV 372, in a top view, thereby providing effective FTV-FTV isolation. In the example of FIG. 9, the FTV 372 has a width of 4 gate pitches, similar to the example of FIG. 3, and may thus provide for reduced resistance. As further shown in the example of FIG. 9, and like the example of FIG. 3, the FTV 372 may extend beyond the upper and lower edges of the VDR 370 in the Y-direction, while having substantially overlapping lateral edges in the X-direction, in the top view. Additionally, as shown in the top view of FIG. 9 and similar to the example of FIG. 3, the upper and lower edges of the set of contact metal layers 360A extend beyond the upper and lower edges of the VDR 370, the FTV 372, and the electrical isolation structure 352A in the Y-direction. As previously described, by employing the set of contact metal layers 360A, instead of a single metal contact feature (a merge MD structure) as used in some existing implementations, layout design is simplified and process window is increased, thereby making it easier to maintain process performance. Further, in view of the above discussion, it is evident that backside power routing may be provided using FTVs and the set of contact metal layers 360A to route power from a back side of the memory macro 200 through the middle strap area 500, through one or both of the edge strap areas 400, or through a combination of the middle strap area 500 and one or both of the edge strap areas 400. Also, while not specifically shown, it will be understood that the cross-sectional view of the feedthrough circuit 450 of FIG. 9 may be substantially similar to the cross-sectional view provided in the example of FIG. 4.

With respect to the description provided herein, rather than using a single metal contact feature (e.g., such as a single S/D contact or merge MD layer) to contact an FTV, embodiments discussed herein may provide a plurality of metal contact features (e.g., such as a plurality of S/D contacts or a plurality of slot MD features) to contact the FTV. By employing a plurality of metal contact features (a plurality of slot MD structures), instead of a single metal contact feature (a merge MD structure), layout design is simplified and it is easier to maintain process performance. In addition, embodiments of the present disclosure provide for tuning of an FTV cell size for layout design optimization, including SRAM macro size reduction and device performance improvement.

Thus, one of the embodiments of the present disclosure described a semiconductor device including a first memory cell area, a second memory cell area adjacent to the first memory cell area, and a middle strap area interposing the first memory cell area and the second memory cell area. In some embodiments, the middle strap area includes a feedthrough circuit that electrically couples a first metal layer on a frontside of the semiconductor device to a second metal layer on a backside of the semiconductor device. In some embodiments, the feedthrough circuit includes a plurality of contact metal layers disposed over and electrically coupled to a feedthrough via (FTV).

In another of the embodiments, discussed is a device including a memory macro. In some embodiments, the memory macro includes a memory cell area, a middle strap area disposed adjacent to a first side of the memory cell area, and an edge strap area disposed adjacent to a second side of the memory cell area opposite the first side. In some embodiments, the middle strap area includes a first feedthrough circuit that electrically couples a first metal layer on a frontside of the device to a second metal layer on a backside of the device. In some embodiments, the first feedthrough circuit includes a first plurality of contact metal layers disposed over and electrically coupled to a first feedthrough via (FTV).

In yet another of the embodiments, discussed is a device including a memory cell area, a logic cell area adjacent to the memory cell area, and an edge strap area interposing the memory cell area and the logic cell area. In some embodiments, the edge strap area includes a feedthrough circuit that electrically couples a first metal layer on a frontside of the device to a second metal layer on a backside of the device. In some embodiments, the feedthrough circuit includes a plurality of contact metal layers disposed over and electrically coupled to a feedthrough via (FTV).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first memory cell area;
a second memory cell area adjacent to the first memory cell area; and
a middle strap area interposing the first memory cell area and the second memory cell area, wherein the middle strap area includes a feedthrough circuit that electrically couples a first metal layer on a frontside of the semiconductor device to a second metal layer on a backside of the semiconductor device;
wherein the feedthrough circuit includes a plurality of contact metal layers disposed over and electrically coupled to a feedthrough via (FTV).

2. The semiconductor device of claim 1, wherein the feedthrough circuit further includes a source/drain contact via rail (VDR) disposed over and electrically coupled to the plurality of contact metal layers.

3. The semiconductor device of claim 1, wherein the first metal layer is part of a frontside interconnect structure, and wherein the second metal layer is part of a backside interconnect structure.

4. The semiconductor device of claim 1, further comprising:
an electrical isolation structure that fully surrounds the FTV in a top view to provide FTV-FTV isolation.

5. The semiconductor device of claim 1, wherein in a top view, the FTV extends along a first direction, and wherein the FTV is center-aligned to a plurality of gate structures in the middle strap area that extend along a second direction perpendicular to the first direction.

6. The semiconductor device of claim 1, wherein the FTV has a width equal to 3 gate pitches or 4 gate pitches.

7. The semiconductor device of claim 1, wherein the middle strap area has a width equal to 12 gate pitches or 13 gate pitches.

8. The semiconductor device of claim 4, wherein in the top view, the electrical isolation structure extends along a first direction and the plurality of contact metal layers extend along a second direction perpendicular to the first direction, and wherein first upper and lower edges of each contact metal layer of the plurality of contact metal layers extend beyond second upper and lower edges of the electrical isolation structure in the second direction.

9. The semiconductor device of claim 1, wherein the first and second memory cell areas include static random-access memory (SRAM) cell areas.

10. The semiconductor device of claim 1, wherein in a top view, the FTV extends along a first direction and a plurality of gate structures in the middle strap area extend along a second direction perpendicular to the first direction, wherein a first dimension of the FTV in the first direction is at least three times greater than a gate pitch of the plurality of gate structures, and wherein a second dimension of the FTV in the second direction is at least greater than half the size of the gate pitch but less than one-and-a-half the size of the gate pitch.

11. The semiconductor device of claim 4, wherein in the top view, the electrical isolation structure extends along a first direction and a plurality of gate structures in the middle strap area extend along a second direction perpendicular to the first direction, wherein a first dimension of the electrical isolation structure in the first direction is at least four times greater than a gate pitch of the plurality of gate structures, and wherein a second dimension of the electrical isolation structure in the second direction is at least greater than half the size of the gate pitch but less than one-and-a-half the size of the gate pitch.

12. A device, comprising:
a memory macro including:
a memory cell area;
a middle strap area disposed adjacent to a first side of the memory cell area; and
an edge strap area disposed adjacent to a second side of the memory cell area opposite the first side;
wherein the middle strap area includes a first feedthrough circuit that electrically couples a first metal layer on a frontside of the device to a second metal layer on a backside of the device; and
wherein the first feedthrough circuit includes a first plurality of contact metal layers disposed over and electrically coupled to a first feedthrough via (FTV).

13. The device of claim 12, wherein the edge strap area includes a second feedthrough circuit that electrically couples a third metal layer on the frontside of the device to a fourth metal layer on the backside of the device, and wherein the second feedthrough circuit includes a second plurality of contact metal layers disposed over and electrically coupled to a second FTV.

14. The device of claim 12, further comprising:
a first electrical isolation structure that fully surrounds the first FTV in a top view to provide FTV-FTV isolation.

15. The device of claim 13, further comprising:
a second electrical isolation structure that fully surrounds the second FTV in a top view to provide FTV-FTV isolation.

16. The device of claim 14, wherein in the top view, the first electrical isolation structure extends along a first direction and the first plurality of contact metal layers extend along a second direction perpendicular to the first direction, and wherein first upper and lower edges of each contact metal layer of the first plurality of contact metal layers extend beyond second upper and lower edges of the first electrical isolation structure in the second direction.

17. The device of claim 15, wherein in the top view, the second electrical isolation structure extends along a first direction and the second plurality of contact metal layers extend along a second direction perpendicular to the first direction, and wherein first upper and lower edges of each contact metal layer of the second plurality of contact metal layers extend beyond second upper and lower edges of the second electrical isolation structure in the second direction.

18. A device, comprising:
a memory cell area;
a logic cell area adjacent to the memory cell area; and
an edge strap area interposing the memory cell area and the logic cell area, wherein the edge strap area includes a feedthrough circuit that electrically couples a first metal layer on a frontside of the device to a second metal layer on a backside of the device;
wherein the feedthrough circuit includes a plurality of contact metal layers disposed over and electrically coupled to a feedthrough via (FTV).

19. The device of claim 18, further comprising:
an electrical isolation structure that fully surrounds the FTV in a top view to provide FTV-FTV isolation.

20. The device of claim 19, wherein in the top view, the electrical isolation structure extends along a first direction and a plurality of gate structures in the edge strap area extend along a second direction perpendicular to the first direction, wherein a first dimension of the electrical isolation structure in the first direction is at least four times greater than a gate pitch of the plurality of gate structures, and wherein a second dimension of the electrical isolation structure in the second direction is at least greater than half the size of the gate pitch but less than one-and-a-half the size of the gate pitch.
